(19) United States
(12) Patent Application Publication
(10) Pub. No.: US 2025/0336651 A1
(43) Pub. Date: Oct. 30, 2025

(54) Plasma-Processing Device, and Plasma-Processing Method

(71) Applicant: Tokyo Electron Limited, Tokyo (JP)

(72) Inventor: Jun YAMAWAKU, Yamanashi (JP)

(21) Appl. No.: 19/262,806

(22) Filed: Jul. 8, 2025

Related U.S. Application Data
(63) Continuation of application No. PCT/JP2024/000201, filed on Jan. 9, 2024.

(30) Foreign Application Priority Data
Jan. 20, 2023 (JP) 2023-007545

(51) Int. Cl. H01J 37/32

(52) U.S. Cl. CPC H01J 37/32651; H01J 37/3244; H01J 2237/3321

(57) ABSTRACT

A plasma processing apparatus comprises: a placing table in a processing chamber for placing a substrate; a plasma generation space constituting a plasma generation mechanism to convert a processing gas into plasma; a processing gas supply part for supplying the gas to the plasma generation space; a perforated plate at a position where the processing gas converted into plasma flows out, the plate having through-holes for passing activated processing gas; and an ion shielding member provided in the through-holes, having an ion shielding surface intersecting a direction of incidence of ions contained in the processing gas converted into plasma, and configured to allow the activated gas to pass through the through-hole while blocking ion incidence via the ion shielding surface.

### CROSS-REFERENCE TO RELATED APPLICATIONS

This application is a bypass continuation application of International Application No. PCT/JP2024/000201 having an international filing date of Jan. 9, 2024 and designating the United States, the International Application being based upon and claiming the benefit of priority from Japanese Patent Application No. 2023-007545 filed on Jan. 20, 2023, the entire contents of which are incorporated herein by reference.

### TECHNICAL FIELD

The present disclosure relates to a plasma processing apparatus and a plasma processing method.

### BACKGROUND

In atomic layer deposition (ALD), which is suitable for forming a film of a fine pattern, plasma may be used to enhance the reactivity of a processing gas such as a reactive gas and to lower a process temperature. In such a plasma ALD method (PEALD), in order to prevent damages to a substrate or the inside of a processing chamber due to discharge or ions, a remote plasma method, in which a plasma generation space is provided at a position separated from a processing space and a processing gas activated by plasma generated in the plasma generation space is supplied, may be adopted.

Even with such a remote plasma method, some of ions and electrons contained in the plasma may leak into the processing space and may induce discharge in the processing space. The occurrence of discharge within the processing space can cause damages to the substrate to be processed or to the members in the processing chamber. Japanese Laid-open Patent Publication No. 2019-203155 discloses a technique in which an ion trap is arranged directly below a shower plate constituting a remote plasma source, in order to prevent ions from leaking into a processing space.

### SUMMARY

The present disclosure provides a technique capable of suppressing the passage of ions when a processing gas activated by plasma passes through through-holes provided in a perforated plate.

According to an aspect of the disclosure, a plasma processing apparatus for performing plasma processing by supplying a processing gas activated by plasma to a substrate in a processing chamber, comprising: a placing table provided in the processing chamber and configured to place the substrate; a plasma generation space constituting a plasma generation mechanism configured to convert the processing gas into plasma; a processing gas supply part configured to supply the processing gas to the plasma generation space; a perforated plate provided at a position where the processing gas converted into plasma flows out of the plasma generation space, the perforated plate having a plurality of through-holes through which the processing gas activated by plasma passes; and an ion shielding member provided in the plurality of through-holes, having an ion shielding surface disposed to intersect a direction in which ions contained in the processing gas converted into plasma are incident toward the through-holes, and configured to allow the activated processing gas to pass through the through-holes where the incidence of ions is blocked by the ion shielding surface.

### BRIEF DESCRIPTION OF THE DRAWINGS

FIG. 1 is a longitudinal side view showing a film forming apparatus according to a first embodiment of the present disclosure.

FIG. 2 is an exploded perspective view showing a showerhead in the first embodiment.

FIG. 3 is a longitudinal side view showing an ion shielding member in the first embodiment.

FIG. 4 is an explanatory diagram showing the function of the ion shielding member in a radical supply process.

FIG. 5 is a longitudinal side view showing an ion shielding member in a second embodiment.

FIGS. 6A and 6B are a longitudinal side view and a plan view, respectively, showing an ion shielding member in a third embodiment.

FIG. 7 is an explanatory diagram showing the function of the ion shielding member in the radical supply process.

FIGS. 8A and 8B are a longitudinal side view and a plan view, respectively, showing an ion shielding member in a fourth embodiment.

FIGS. 9A and 9B are a longitudinal side view and a plan view, respectively, showing an ion shielding member in a modification of the fourth embodiment.

FIG. 10 is a longitudinal side view showing a film forming apparatus according to a fifth embodiment of the present disclosure.

### DETAILED DESCRIPTION

### First Embodiment

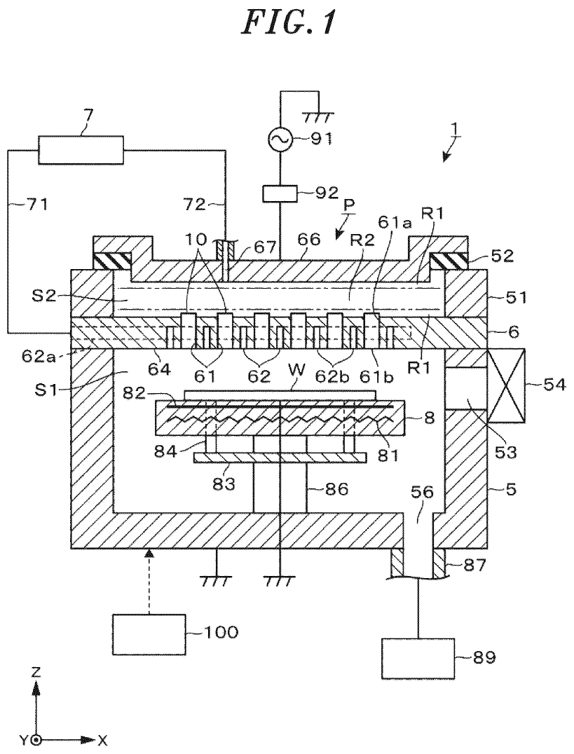

Hereinafter, as a first embodiment of a plasma processing apparatus according to the present disclosure, a film forming apparatus 1 for forming a film by a plasma-enhanced atomic layer deposition (PEALD) method on a semiconductor wafer W (hereinafter, referred to as “substrate W”) that is a substrate will be described with reference to FIG. 1. FIG. 1 is a longitudinal side view showing the film forming apparatus 1 according to the present embodiment. The film forming apparatus 1 includes a processing space S1 where the substrate W is placed, and a plasma generating mechanism P that is provided above the processing space S1 and converts a processing gas into plasma. Further, the film forming apparatus 1 is configured to form atomic layers one by one on the substrate W by sequentially supplying various processing gases including a gas activated by plasma to the processing space S1. In the film forming apparatus 1, the film forming efficiency can be improved by quickly supplying and replacing various processing gases and increasing the density or temperature of the plasma by the plasma generating mechanism P.

The film forming apparatus 1 includes a processing chamber 5 including a processing space S1, a shower head 6, an annular member 51, and an upper lid 66. The processing chamber 5 has an upper opening, and the shower head 6 is attached to the upper opening. The annular member 51 has an upper opening and a bottom opening, and is attached to the processing chamber 5 via the shower head 6 located to close the bottom opening. The upper lid 66 is attached to the upper opening of the annular member 51 via an annular insulating member 52, and the upper lid 66 is located to close the upper opening of the annular member 51. The upper lid 66 and the shower head 6 are located to face each other.

The film forming apparatus 1 includes a plasma generation space S2 surrounded by the shower head 6, the annular member 51, the insulating member 52, and the upper lid 66. The plasma generation space S2 is located to be contact with the processing space S1 in the processing chamber 5 via the shower head 6. The shower head 6 is provided between the plasma generation space S2 and the processing space S1, and separates the spaces S1 and S2 from each other. The processing chamber 5, the shower head 6, the annular member 51, and the upper lid 66 are made of a metal. The processing chamber 5 is grounded.

A loading/unloading port 53 for loading/unloading the substrate W and a gate valve 54 for opening/closing the loading/unloading port 53 are provided on the sidewall of the processing chamber 5. A placing table 8 for horizontally placing the substrate W is provided in the processing chamber 5. The placing table 8 is located below the shower head 6 to face the shower head 6. A substrate heater 81 is embedded in the placing table 8, and the substrate heater 81 heats the substrate W to a preset temperature by a power supplied from a power supply (not shown). The placing table 8 is made of insulating ceramic such as aluminum nitride (AlN) or the like, and a disc-shaped electrode 82 is located therein. The electrode 82 is grounded.

The placing table 8 is provided with three substrate support pins 84 (only two shown) that can be raised and lowered with respect to the surface of the placing table 8 to support and raise and lower the substrate W, and these substrate support pins 84 are fixed to a support plate 83. The substrate support pins 84 are raised and lowered via the support plate 83 by a driving mechanism (not shown) such as an air cylinder or the like.

The placing table 8 is supported by a cylindrical support 86, and the support 86 is attached to the bottom portion of the processing chamber 5. The processing chamber 5 has a heating mechanism (not shown), and they are heated to a preset temperature by a power supplied from a power supply (not shown). An exhaust line 87 is connected to an opening 56 at the bottom portion of the processing chamber 5, and an exhaust device 89 is connected to the exhaust line 87. The opening 56 at the bottom portion of the processing chamber 5 and the exhaust line 87 form an exhaust channel to exhaust a processing gas in the processing space S1. By operating the exhaust device 89, the processing space S1 of the processing chamber 5 can be depressurized to a preset vacuum level.

The film forming apparatus 1 includes a processing gas supply part 7 for supplying a processing gas to the processing space S1 via the shower head 6. The processing gas supply part 7 supplies s processing gas used in PEALD film formation, such as a raw material gas containing elements of a film to be formed, a reactive gas that reacts with the raw material gas, and a purge gas. Various raw material gases and reactive gases can be used depending on a film to be formed. An inert gas, such as a rare gas such as Ar (argon) gas or He (helium) gas, or N₂ (nitrogen) gas can be used as the purge gas.

The processing gas supply part 7 alternately and intermittently supplies a raw material gas and a reactive gas while continuously supplying a purge gas during film formation. The lines for supplying the processing gases include a raw material gas supply line 71 for supplying a raw material gas and a purge gas, and a reactive gas supply line 72 for supplying a reactive gas and a purge gas, which are connected to the processing gas supply part 7. The lines for supplying the processing gases are provided with valves and flow rate controllers such as mass flow controllers.

The plasma generation mechanism P is constituted by the plasma generation space S2 described above, a radio frequency (RF) power supply 91, and the upper lid 66 and the shower head 6 that form parallel plate electrodes for generating an electric field in the plasma generation space S2. The shower head 6 is grounded via the processing chamber 5. The RF power supply 91 is connected to the upper lid 66 via a matching box 92, and the RF power is supplied from the RF power supply 91. The frequency of the RF power supply 91 may be set to 13.56 MHz within the range of 450 kHz to 40 MHz, for example.

The upper lid 66 has a reactive gas inlet hole 67 penetrating through the upper lid 66, and the downstream end of the reactive gas supply line 72 is connected to the reactive gas inlet hole 67. In a radical supply process to be described later, the reactive gas supplied to the plasma generation space S2 is ionized by the electric field formed by the parallel plate electrodes through the power supply, thereby becoming plasma. In this case, in the gap between the parallel plate electrodes, sheath regions R1 are formed in the vicinity of each of the parallel plate electrodes, and the space between the sheath regions R1 serves as a plasma region R2 where the plasma of the reactive gas in an equilibrium state is generated.

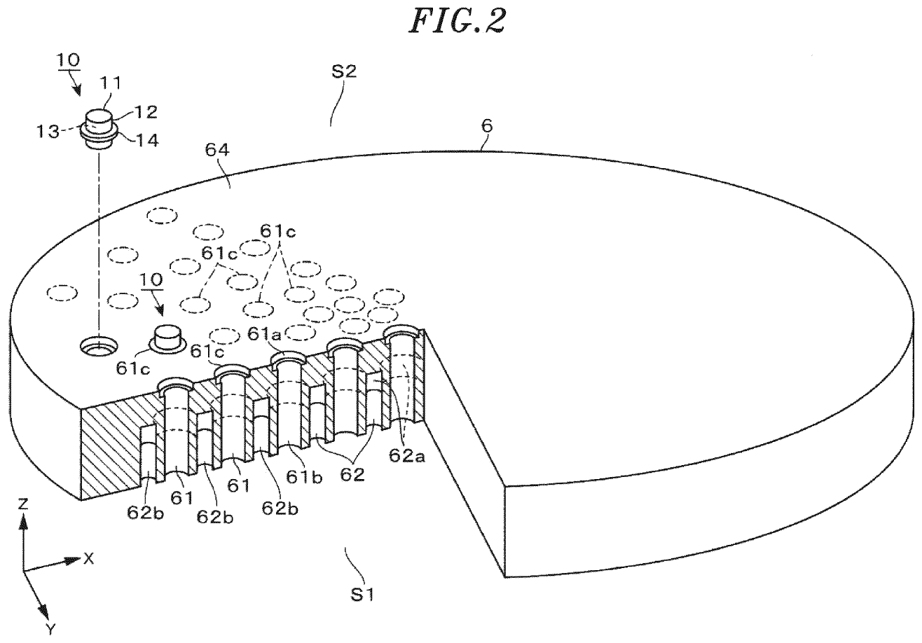

As shown in FIGS. 1 and 2, in the shower head 6, reactive gas channels 61 (through-holes) for circulating a reactive gas and raw material gas channels 62 for circulating a raw material gas are formed separately from each other. Hereinafter, “reactive gas channels 61” are also referred to as “through-holes 61”. FIG. 2 is an exploded perspective view showing the internal structure of the shower head 6. In FIG. 2, the through-holes 61, the raw material gas channels 62, and an ion shielding member 10 to be described later only in a part of the shower head 6 are illustrated, and the illustration thereof in the other part is omitted. As shown in FIG. 2, the raw material gas channels 62 includes a distribution passage 62a and a plurality of downstream passages 62b branched from the distribution passage 62a. In FIGS. 1 and 2, the distribution passage 62a is indicated by a dashed line and a solid line.

The distribution passage 62a is formed in the shower head 6. One end of the distribution passage 62a is opened on the side surface of the shower head 6 (see FIG. 1), and is connected to the downstream end of the raw material gas supply line 71 described above. Further, the distribution passage 62a is formed directly above the substrate W, and is formed to spread out in a planar shape or in a radial shape in plan view. The plurality of downstream passages 62b are formed to extend from the bottom surface of the distribution passage 62a toward the bottom surface of the shower head 6, and are opened to the bottom surface of the shower head 6. The plurality of downstream passages 62b are distributed substantially uniformly in the region of the shower head 6 that is located directly above the substrate W in plan view.

The through-holes 61 penetrate through the shower head 6 from the upper surface to the bottom surface thereof, and connect the plasma generation space S2 and the processing space S1. The plurality of through-holes 61 are spaced apart from each other in plan view. The upper openings 61a and the lower openings 61b of the through-holes 61 are distributed substantially uniformly in the region directly above the substrate W in plan view. In each through-hole 61, an upper hole edge portion 61c having a diameter greater than that of the other portion on the lower side may be formed at the upper opening 61a. The diameter of each through-hole 61 is, e.g., 3 mm to 9 mm.

The plurality of through-holes 61 are spaced apart from the raw material gas channels 62 described above. Further, the plurality of through-holes 61 are arranged substantially uniformly in the region directly above the substrate W on the bottom surface of the shower head 6. The shower head 6 corresponds to the perforated plate of the present disclosure.

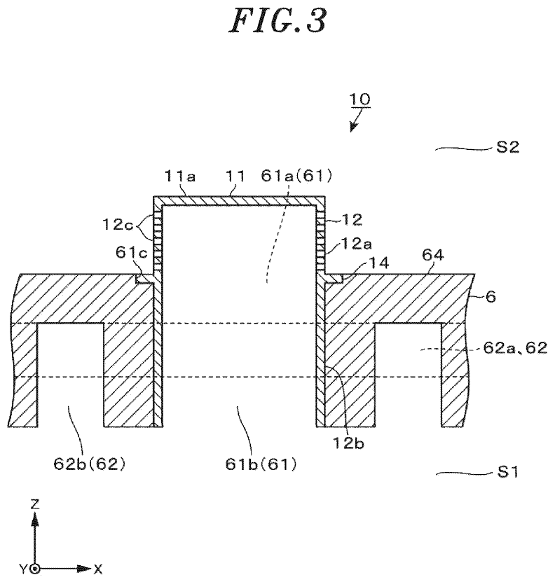

The ion shielding member 10 is provided in each through-hole 61 of the shower head 6 configured as described above. As shown in FIGS. 2 and 3, the ion shielding member 10 is formed in a cap shape including a ceiling plate portion 11 and a cylindrical sidewall portion 12 extending downward from the ceiling plate portion 11. In addition, an annular flange portion 14, which is provided at a height position above the lower end of the sidewall portion 12 and protrudes outward, is formed on the outer peripheral surface of the sidewall portion 12.

The ion shielding member 10 is attached to the shower head 6 by inserting the lower end of the sidewall portion 12 into the through-hole 61 from the position above the shower head 6 with the ceiling plate portion 11 facing upward, and engaging/fitting the flange portion 14 with the upper hole edge portion 61c of the through-hole 61.

FIG. 3 shows a longitudinal side view of the ion shielding member 10 attached to the shower head. In this state, the ion shielding member 10 is attached by the contact between the bottom surface of the flange portion 14 and the inner upper surface of the upper hole edge portion 61c of the shower head 6. In this attached state, the sidewall portion 12 is located with a lower sidewall portion 12b below the flange portion 14 inserted into the through-hole 61. Further, a upper sidewall portion 12a of the sidewall portion 12, which is located above the flange portion 14, and the ceiling plate portion 11 are arranged to protrude upward with respect to/from an upper surface 64 (plate surface) of the shower head 6, i.e., toward the plasma generation space S2 side.

The ceiling plate portion 11 has a disc shape, and is arranged so as to cover the through-hole 61 when viewed from the plasma generation space S2 side. In addition, an ion shielding surface 11a, which is the upper surface of the ceiling plate portion 11, is located to intersect the direction in which positive ions C1 to be described later are incident from the plasma region R2 toward the sheath region R1.

The protruding height of the ceiling plate portion 11 from the upper surface 64 of the shower head 6 is set to be less than or equal to the theoretical thickness of the sheath region R1 formed on the surface of the shower head 6. Specifically, the protruding height of the ceiling plate portion 11 refers to the height to the ion shielding surface 11a with respect to the upper surface 64 of the shower head 6, and the height is set to be less than or equal to the thickness of the sheath region R1. The reason for setting the height of the ceiling plate portion 11 as described above will be described later. In addition, the protruding height of the ceiling plate portion 11 is preferably, 1 mm or more, for example, in order to arrange a plurality of sidewall through-holes 12c to be described later in the vertical direction in the upper sidewall portion 12a.

The sidewall portion 12 is formed in a cylindrical shape with a diameter slightly smaller than that of the through-hole 61, and is provided along the inner wall of the through-hole 61. The upper sidewall portion 12a located above the flange portion 14 is formed along the outer periphery of the ceiling plate portion 11, and is located in the plasma generation space S2. In the upper sidewall portion 12a, the plurality of sidewall through-holes 12c are formed to penetrate from the outer wall surface to the inner wall surface, and each sidewall through-hole 12c is opened toward the plasma generation space S2.

For example, the sidewall through-holes 12c are circular holes, and are formed side by side in a row in the height direction in the sidewall portion 12. Further, the sidewall through-holes 12c are arranged in multiple rows along the circumferential direction of the sidewall portion 12. The diameter of the sidewall through-hole 12c is preferably 0.4 mm or more. Accordingly, it is possible to prevent the ion sheath formed on the inner side surface of the sidewall through-holes 12c from blocking the sidewall through-holes 12c. The lower sidewall portion 12b located below the flange portion 14 is formed to have approximately the same length as that of the through-hole 61 in the vertical direction, and the lower end thereof is opened along the opening of the through-hole 61 itself. The outer side surface of the lower sidewall portion 12b is located along the inner side surface of the through-hole 61.

The inner space inside the ceiling plate portion 11 and the cylindrical sidewall portion 12 is connected to the inner openings of the sidewall through-holes 12c. Therefore, even when the ion shielding member 10 is provided, the through-holes 61 are connected to the plasma generation space S2 via the sidewall through-holes 12c and the inner space of the ion shielding member 10. Hence, the reactive gas activated by plasma in the plasma generation space S2 can be supplied to the processing space S1 via the inner space of the ion shielding member 10.

The ion shielding member 10 is made of a metal, and has a surface covered with an oxide film or a dielectric. Specifically, the metal preferably includes at least one of nickel (Ni) and aluminum (AI). The oxide film or the dielectric is preferably aluminum oxide (Al₂O₃), quartz, aluminum nitride (AlN), or the like.

As shown in FIG. 1, the film forming apparatus 1 includes a controller 100. The controller 100 includes a data processing part having a program, a memory, and a CPU. The program includes commands for transmitting control signals from the controller 100 to individual components of the film forming apparatus 1 and for performing processes related to the film forming process. The program is stored in a storage part, such as a computer storage medium, e.g., a flexible disk, a compact disk, a hard disk, a magneto-optical disk (MO), or a non-volatile memory, and is installed in the controller 100. The controller 100 controls and operates the individual components in the film forming apparatus 1 according to an operator's operation and a preset program. In the case of controlling the plasma appropriately according to each process, the controller 100 controls the processing gas supply part 7, the RF power supply 91, and the exhaust device 89.

The operation of performing a film forming process on the wafer W using plasma by the film forming apparatus 1 having the above-described configuration will be described. When the wafer W to be processed is transferred, the gate valve 54 is opened, and a transfer mechanism (not shown) holding the wafer W enters the processing chamber 5 through the loading/unloading port 53. Then, the wafer W is transferred to the placing table 8 using the substrate support pins 84.

Then, the transfer mechanism retracts from the processing chamber 5. The gate valve 54 is closed and, at the same time, the pressure in the processing chamber 5 and the temperature of the wafer W are adjusted. Next, various processing gases are supplied at predetermined timings. In the radical supply process, a reactive gas is supplied to the plasma generation space S2 (step of supplying the processing gas) and, at the same time, the RF power is applied from the RF power supply 91 to the upper lid 66. By applying the RF power to the upper lid 66, capacitively coupled plasma is generated between the upper lid 66 and the shower head 6, and the reactive gas supplied to the plasma generation space S2 is converted into plasma (step of converting the processing gas into plasma). Further, an auxiliary gas such as Ar gas or the like may also be supplied to the reactive gas to be converted into plasma.

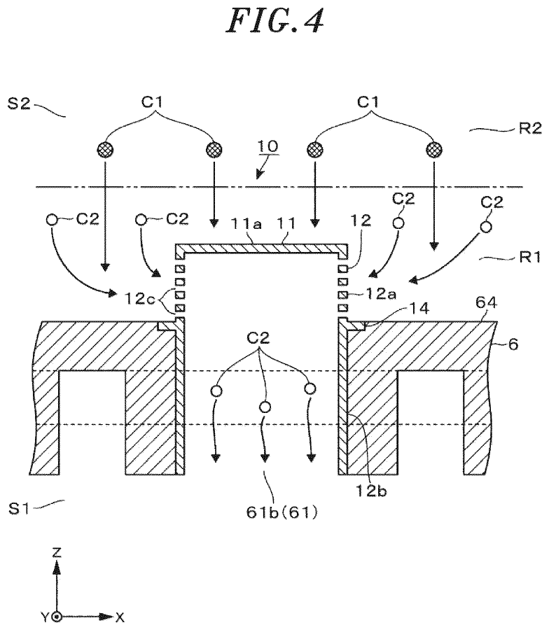

In the above-described film forming process, radicals of the reactive gas activated by the plasma generated in the plasma generation space S2 are supplied to the processing space S1 through the through-holes 61 provided in the shower head 6 (step of allowing the activated processing gas to pass through the through-holes) and are supplied to the substrate W (step of supplying the activated processing gas to the substrate). The action/function of the ion shielding member 10 in the radical supply process will be described below. FIG. 4 shows the action of the ion shielding member 10 during the radical supply process of the film forming apparatus 1.

In the radical supply process, the reactive gas in the plasma state contains active species such as electrons, positive ions (hereinafter, also simply referred to as “ions”) C1, and radicals C2. The active species have the highest density in the plasma region R2 and exist in an electrically neutral state. On the other hand, the density of the reactive gas in a plasma state becomes zero on the upper surface 64 of the shower head 6 where the sheath region R1 is formed. Therefore, the density gradient of the active species occurs in the sheath region R1 toward the upper surface 64 of the shower head 6 where the density is zero. In the sheath region R1 where the density gradient occurs, the potential distribution that prevents the inflow of electrons and attracts the ions C1 occurs in order to prevent electrical imbalance due to an increase in the electrons with diffusion coefficients greater than those of the ions C1. The ions C1 are accelerated to be linearly incident toward the upper surface 64 of the shower head 6. In other words, the incident direction of the ions C1 is the direction directed from the plasma region R2 toward the sheath region R1.

As described in the background art, if the ions C1 enter the processing space S1 through the through-holes 61, discharge occurs, which may cause damage to the wafer W and members/components in the processing chamber 5. Therefore, in the ion shielding members 10 are arranged to cover the through-holes 61 when viewed from the plasma generation space S2 side, thereby blocking the through-holes 61. With this configuration, even if a portion of the ions C1 incident toward the upper surface 64 of the shower head 6 reaches the region where the through-holes 61 are arranged, the ions C1 can be made to collide with the ion shielding surfaces 11a. The ions C1 colliding with the ion shielding surfaces 11a are, for example, deactivated.

In this manner, the ion shielding members 10 prevent the ions C1 from passing through the through-holes 61 and entering the processing space S1. Therefore, if the ions C1 enter the processing space S1, the ion shielding members 10 suppress the occurrence of discharge in the processing space S1, and prevent damages to the substrate W and the components in the processing chamber 5.

From this perspective, FIG. 4 shows an example in which one ceiling plate portion 11 is located at a position protruding upward with respect to the upper surface 64 of the shower head 6. However, the arrangement example of the ion shielding member 10 configured in a cap shape is not limited thereto. For example, it suffices that the ion shielding member 10 covers the through-holes 61 in plan view from the upper side, and the ion shielding member 10 having a plurality of ceiling plate portions 11 arranged alternately at different height positions may be also provided.

Compared to the behavior of the ions C1 described above, the radicals C2, which are active species, are electrically neutral. Therefore, the radicals C2 tend to move with the flow of the reactive gas from the plasma generation space S2 toward the processing space S1. The radicals C2 moving with the flow of the reactive gas flow into the ion shielding member 10 through the sidewall through-holes 12c, and then flow into the processing space S1. Even if the radicals C2 are brought into contact with the ion shielding member 10 when flowing into the processing space S1 through the ion shielding member 10, the radicals C2 are not easily deactivated because the surface of the ion shielding member 10 is covered with an oxide film or a dielectric.

In the ion shielding member 10 of this example, the diameter of the cylindrical sidewall portion 12 is formed to follow along the inner wall of the through-hole 61, so that the channel cross-sectional area can be increased. The flows that have passed through the multiple sidewall through-holes 12c join together in the ion shielding member 10 and flow downward. At this time, the flows can flow linearly from the upstream side toward the downstream side. Therefore, the space formed by the sidewall through-holes 12c and the space in the ion shielding member 10 can prevent deactivation and allow a large amount of radicals C2 to flow into the processing space S1, compared to when the radicals flow through a curved complex channel, for example.

Further, as described above, in the ion shielding member 10, the protruding height of the ceiling plate portion 11 is less than or equal to the thickness of the sheath region R1, so that the upper sidewall portion 12a of the ion shielding member 10 does not enter the plasma region R2. By setting the protruding height of the ceiling plate portion 11 as described above, the sidewall through-holes 12c provided in the upper sidewall portion 12a are prevented from being opened toward the plasma region R2, and the ions C1 in the reactive gas in a plasma state are prevented from directly entering the ion shielding member 10. In this manner, the plasma is prevented from leaking into the processing chamber 5. As described above, in the ion shielding member 10 of the present embodiment, it is possible to prevent the accelerated ions from passing through the through-holes 61, and to allow the radicals to efficiently flow toward the processing chamber 5.

In the above film forming process, in the case of forming a film by a CVD method, the radical supply process for supplying radicals of the reactive gas in a plasma state and the raw material gas supply process for supplying a raw material gas may be performed in parallel. In addition, in the case of forming a film by a PEALD method, a cycle of a process of supplying a source gas (adsorption of a precursor to the wafer W)→a process of supplying only a purge gas→a radical supply process (reaction with the precursor adsorbed to the wafer W)→a process of supplying only a purge gas is repeated a predetermined number of times, for example.

After performing the film formation by the CVD method or the PEALD method for a predetermined period of time, the supply of the reactive gas and the source gas, and the supply of the RF power to the shower head 6 and the upper lid 66 are stopped. Thereafter, the wafer W on which the film has been formed is unloaded from the processing chamber 5 in the reverse order of the loading operation.

### (Modification)

The plasma generating mechanism P of the film forming apparatus 1 in the first embodiment described above generates capacitively coupled plasma (CCP) using capacitive coupling by parallel plate electrodes. However, the present disclosure is not limited thereto, and the plasma generating mechanism P may use various methods. For example, the plasma generating mechanism P may have a coil-shaped antenna instead of the parallel plate electrodes, and generate inductively coupled plasma (ICP) by the antenna to which an RF power is applied. In addition, the plasma generating mechanism P may have a plate-shaped dielectric in the plasma generating space S2 instead of the parallel plate electrodes, and supply microwaves to the dielectric to generate surface wave plasma (SWP) by the surface waves emitted from the dielectric.

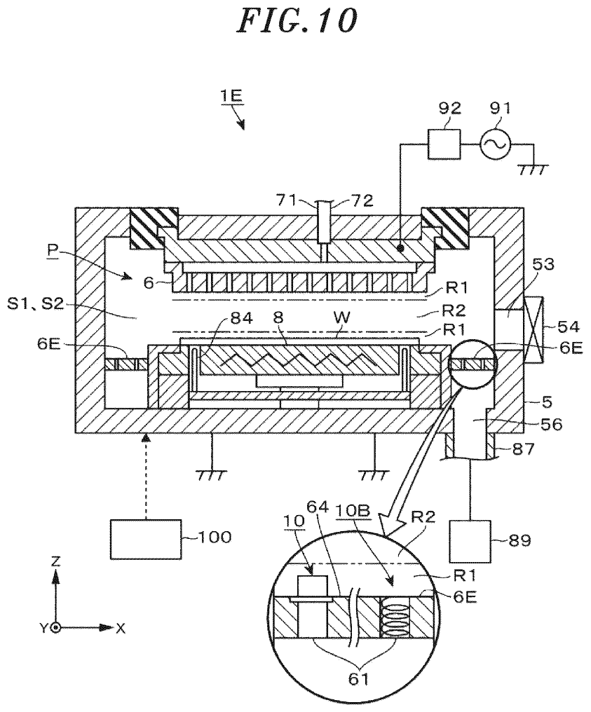

The film forming apparatus 1 in the first embodiment is a remote plasma type film forming apparatus 1 in which the plasma generating space S2 is spaced apart from the processing space S1, and the shower head 6 corresponds to a perforated plate. However, the present disclosure is not limited thereto. Other examples will be described in the following embodiments (see FIG. 10).

The shower head 6 in the first embodiment is provided with the through-holes 61 and the raw material gas channels 62. However, the present disclosure is not limited thereto, and the shower head may have only the through-holes 61, for example. In this case, the raw material gas channels 62 may be formed in, e.g., a nozzle located in the processing space S1, and the raw material gas may be supplied to the substrate W through the nozzle. Further, in this case, the upper surface of the shower head 6 except the through-holes 61 and the upper hole edge portion 61c is formed as a flat surface. However, the present disclosure is not limited thereto. For example, the upper hole edge portion 61c and its periphery on the upper surface of the shower head 6 may be recessed toward the processing space S1, and the upper hole edge portion 61c may be located further below the upper surface of the shower head 6 outside the periphery. If the ion shielding member 10 is attached to the upper hole edge portion 61c located further below the upper surface of the shower head 6, the amount of protrusion of the ion shielding member 10 from the shower head 6 can be reduced.

In the first embodiment, the ion shielding members 10 are attached while being inserted into the through-holes 61 from the plasma generation space S2 side. However, the present disclosure is not limited thereto. For example, the ion shielding members 10 may be inserted into the through-holes 61 from the processing space S1 side, for example. In this case, the flange portion 14 is attached to be in contact with the hole edge of the lower opening 61b of the shower head 6. Further, the sidewall portion 12 extends from the lower opening 61b into the through-holes 61, and the ceiling plate portion 11 and the upper sidewall portion 12a protrude into the plasma generation space S2. In this case as well, the ceiling plate portions 11 can cover the through-holes 61 when viewed from the plasma generation space S2 side. In this example, the formation of the lower sidewall portion 12b extending downward from the flange portion 14 may be omitted.

In addition, in the first embodiment shown in FIGS. 3 and 4, the example in which the cap-shaped ion shielding member 10 is attached such that the ceiling plate portion 11 is located above the flange portion 14 is illustrated. Instead of this example, the ion shielding member 10 may be turned upside down. In this case, for example, the ion shielding member 10 is attached such that the flange portion 14 is brought into contact with the hole edge portion on the lower side of the through-hole 61 on the bottom surface of the shower head 6. The ceiling plate portion 11 (which may be seen as the bottom plate when the plate is turned upside down) covers the lower opening of the through-hole 61. In this case, the ceiling plate portion 11 can be located to cover the through-hole 61 as viewed from the plasma generation space S2.

The lower sidewall portion 12b in the first embodiment is provided in the region extending the upper opening 61a to the lower opening 61b of the through-hole 61. However, the present disclosure is not limited thereto, and the lower end of the lower sidewall portion 12b may be located in the middle of the through-hole 61. In addition, it is not necessary that the ion shielding member 10 has the lower sidewall portion 12b. For example, the formation of the lower sidewall portion 12b may be omitted, and the lower end of the upper sidewall portion 12a may be attached directly to the periphery of the upper opening or lower opening of the through-hole 61.

The ion shielding members 10 in the first embodiment are independent from each other. However, the present disclosure is not limited thereto, and the ion shielding members 10 may be integrated. For example, the plurality of ion shielding members 10 may be formed so as to protrude from a single flat plate. In the case of a flat plate, the plurality of ion shielding members 10 can be attached to the upper surface 64 or the bottom surface of the shower head 6 at once.

The through-hole 61 in the first embodiment is a circular hole. However, the present disclosure is not limited thereto, and the through-hole 61 may be a hole having another shape such as a rectangular hole (the same in the embodiments to be described later). The ceiling plate portion 11 and the sidewall portion 12 have a disc shape and a cylindrical shape, respectively. However, the present disclosure is not limited thereto, and may have another shape such as a rectangular shape and a square columnar shape. Further, the ceiling plate portion 11 and the sidewall portion 12 have a disc shape and a cylindrical shape to correspond to the through-hole 61. However, the present disclosure is not limited thereto, and the ceiling plate portion 11 and the sidewall portion 12 may have other shapes different from that of the through-hole 61.

The sidewall through-hole 12c is not limited to a circular hole, and may be a slit-shaped hole. Further, the sidewall through-hole 12c may be formed by cutting out most of the upper sidewall portion 12a. In this case, the configuration in which the columnar upper sidewall portions 12a that connect the ceiling plate portion 11 and the lower sidewall portion 12b are arranged at intervals to support the ceiling plate portion 11 may be adopted, for example.

The ion shielding member 10 in the first embodiment is made of a metal and has a surface covered with an oxide film or a dielectric. However, the present disclosure is not limited thereto. For example, when the film forming apparatus 1 performs a film forming process using low-temperature plasma, the ion shielding member 10 made of a metal may not be covered with an oxide film or a dielectric. Further, the ion shielding member 10 may be made of a dielectric material instead of a metal. In this case, the heat resistance is improved and the deactivation of radicals can be suppressed. Further, although the ion shielding member 10 is entirely made of a metal, the present disclosure is not limited thereto, and the ion shielding member 10 may be partially made of different materials as will be described in a next embodiment.

### Second Embodiment

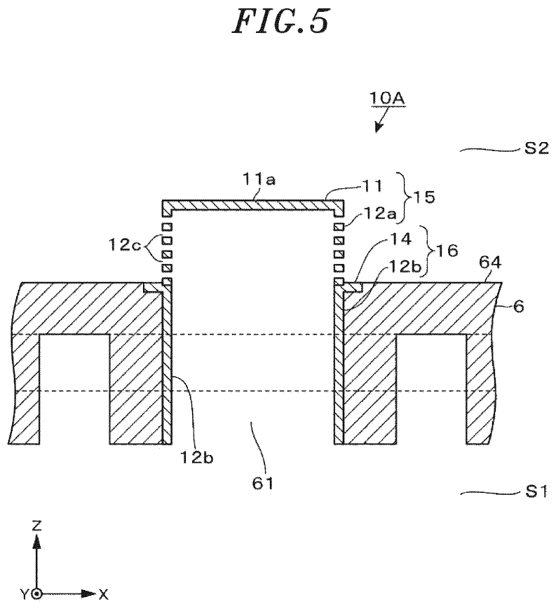

An ion shielding member 10A in a second embodiment of the present disclosure will be described with reference to FIG. 5. In the following description of each embodiment, the differences from the first embodiment will be mainly described, and the description of the same configuration as that of the first embodiment will be omitted. In addition, like reference numerals are used for like parts that are common to those described with reference to FIGS. 1 to 4. FIG. 5 shows a longitudinal cross-sectional view of the ion shielding member 10A which is the same as that shown in FIG. 3.

In the ion shielding member 10A of the second embodiment, an upper part 15 including the ceiling plate portion 11 and the upper sidewall portion 12a is integrally made of a metal as in the first embodiment, and has a surface covered with an oxide film or a dielectric. On the other hand, a lower part 16 including the lower sidewall portion 12b and the flange portion 14 of the ion shielding member 10A is integrally made of a dielectric. The upper part 15 and the lower part 16, which are made of different materials, are integrated by attaching the lower end of the upper part 15 to the lower part 16. The metal upper part 15 attached on the dielectric lower part 16 is electrically floating. In addition, since the upper part 15 is located closer to the plasma region R2 than the upper surface of the shower head 6, the floating potential of the upper part 15 is closer to the potential of the plasma region R2 than the potential of the sheath region R1 around the upper part 15. Since the potential of the upper part 15 is closer to the plasma potential, the discharge from the plasma region R2 toward the peripheral edge of the ceiling plate portion 11, which forms the corner portion where the electric field is likely to concentrate, can be suppressed.

### Third Embodiment

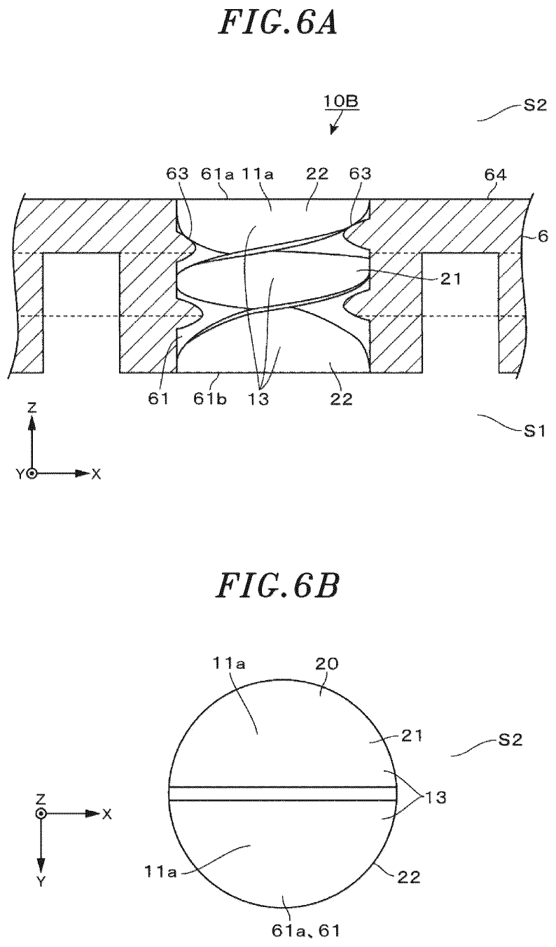

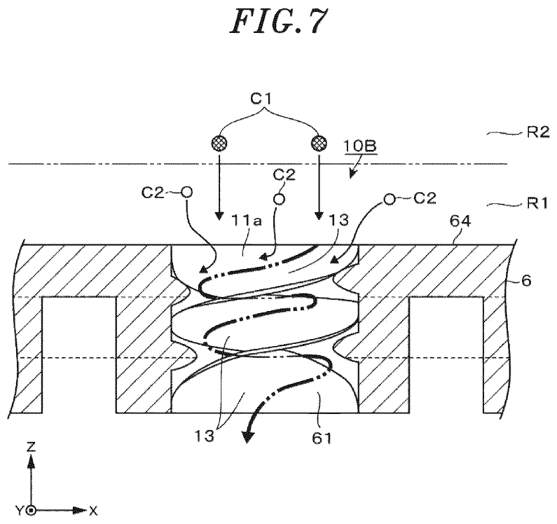

An ion shielding member 10B in a third embodiment of the present disclosure will be described with reference to FIGS. 6 and 7. FIG. 6A shows a longitudinal side view of the ion shielding member 10B, and FIG. 6B is a plan view of the ion shielding member 10B. FIG. 7 shows the function of the ion shielding member 10B in the radical supply process. The dashed double-dotted line in FIG. 7 indicates the flow of the reactive gas. When viewed from the position facing FIG. 7, the thick lines indicate the flow passing through the front side of the ion shielding member 10B, and the thin lines indicate the flow passing through the rear side of the ion shielding member 10B.

The ion shielding member 10B of the third embodiment is a spiral-shaped member formed along the vertical central axis of the through-hole 61, and is entirely located inside the through-hole 61. As shown in FIGS. 6A and 6B, the ion shielding member 10B is configured in a shape that an elongated ribbon-shaped member 20 having a width corresponding to the opening diameter of the through-hole 61 is twisted 360 degrees or more around the central axis along the longitudinal direction.

The front surface 21 and the rear surface 22 of the ribbon-shaped member 20 facing each other are shaped to be twisted in the same direction 360 degrees or more. Each of the front surface 21 and the rear surface 22 is a spiral surface inclined from the upper opening 61a toward the lower opening 61b of the through-hole 61. Further, the front surface 21 and the rear surface 22 form connection passages 13 with the inner wall surface of the through-hole 61. In other words, the two connection passages 13 form a spiral-shaped channel inclined from the upper opening 61a toward the lower opening 61b of the through-hole 61 while facing each other via the ion shielding member 10B.

In the ion shielding member 10B of this example, the ion shielding surfaces 11a are formed by the upper end surfaces of the front surface 21 and the rear surface 22 of the ribbon-shaped member. The ion shielding surfaces 11a are arranged to face the plasma generation space S2.

The through-hole 61 has double-spiral-shaped protrusions 63 formed along the inner wall surface thereof. The ion shielding member 10B is attached when screwed-fitted along the protrusions 63. With this configuration, the ion shielding member 10B can be fitted into the through-hole 61 from either the upper surface or the bottom surface of the shower head 6, which makes the installation process easy.

As shown in FIG. 7, in accordance with the ion shielding member 10B of the third embodiment, even if the ions C1 are incident on the through-holes 61 from the plasma region R2 in the radical supply process, the ions C1 collide with the ion shielding surface 11a and are prevented from passing through the through-holes 61. On the other hand, the reactive gas radicals C2 move with the flow of the reactive gas and pass through the two connection passages 13 and are supplied to the processing space S1.

The ion shielding member 10B of the third embodiment shown in FIGS. 6 and 7 has a configuration in which the elongated ribbon-shaped member 20 is twisted 360 degrees or more around the central axis. However, the twist angle of the ribbon-shaped member 20 may be 180 degrees or more. In the configuration in which the ribbon-shaped member 20 is twisted at least 180 degrees, each of the front surface 21 and the rear surface 22 of the ribbon-shaped member 20 forms the ion shielding surface 11a that covers half of the through-hole 61 when viewed from the plasma generation space S2 side, which makes it possible to block the passage of the ions C1 through the through-holes 61.

### Fourth Embodiment

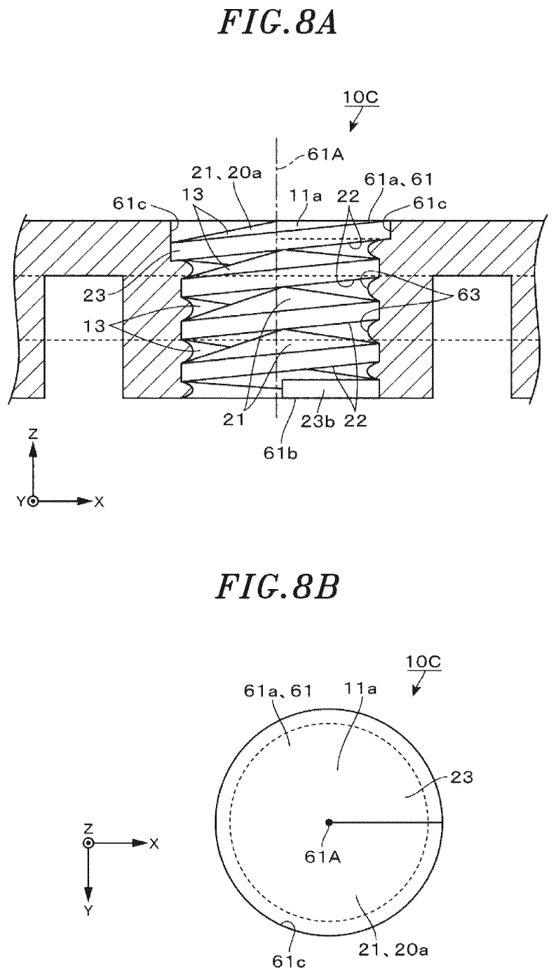

An ion shielding member 10C in a fourth embodiment of the present disclosure will be described based on FIGS. 8A and 8B. Similarly to FIGS. 6 and 7 of the third embodiment, FIGS. 8A and 8B are a longitudinal side view and a plan view, respectively, showing the ion shielding member 10C of the fourth embodiment. In the ion shielding member 10C of the fourth embodiment, a member (slope-shaped member 20a) that spirals in a slope shape is located around a central axis 61A set along the vertical direction of the through-hole 61. Specifically, in the ion shielding member 10C, the slope-shaped member 20a is wound around the above-described central axis 61A with the front surface 21 facing upward, for example.

Further, the connection passage 13 is formed between the inner wall surface of the through-hole 61 and the front surface 21 and the rear surface 22. The connection passage 13 is formed as a spiral-shaped channel that spirals from the upper opening 61a toward the lower opening 61b of the through-hole 61.

As shown in FIGS. 8A and 8B, in the ion shielding member 10C of this example, an upper end 23 side of the slope-shaped member 20a is widened by the range of one spiral turn, thereby forming the ion shielding surface 11a. Further, a single spiral protrusion 63 is formed along the inner wall surface of the through-hole 61. The ion shielding member 10C is attached when screw-fitted to the through-hole 61 along the protrusion 63. Further, the upper end 23 forming the widened portion described above is accommodated inside the widened upper hole edge portion 61c on the upper side of the through-hole 61.

### (Modification)

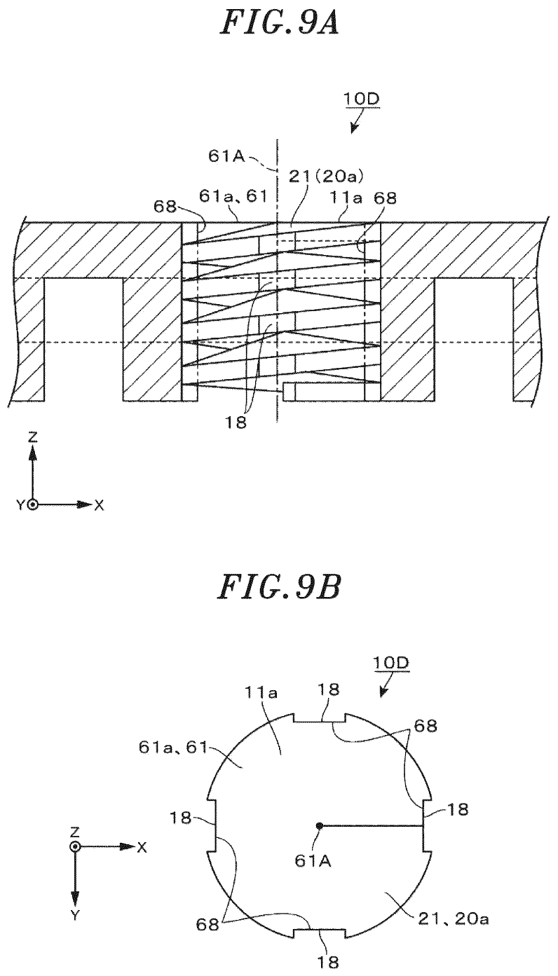

An ion shielding member 10D in a modification of the fourth embodiment of the present disclosure will be described with reference to FIGS. 9A and 9B. The ion shielding member 10D in this modification is different from the ion shielding member 10C in the fourth embodiment in the method of attachment to the through-hole 61. The through-hole 61 does not have a single-spiral protrusion 63, unlike the fourth embodiment. Instead, four ribs 68 are provided to protrude from the inner wall of the through-hole 61 toward the central axis 61A when viewed from the plasma generation space S2 side. The ribs 68 are provided at intervals in the circumferential direction of the inner wall of the through-hole 61, and are formed to extend in the vertical direction parallel to the central axis 61A. The ion shielding member 10D has four grooves 18 to be engaged with the ribs 68. Unlike the ion shielding member 10C described with reference to FIGS. 8A and 8B, the upper end of the ion shielding member 10D of this example does not have a widened portion.

The ion shielding member 10D is attached to the through-hole 61 when inserted from the upper side or the lower side so that the grooves 18 are engaged with the ribs 68 on the through-hole 61 side. Due to the engagement between the ribs 68 and the grooves 18, the rotation and movement of the shielding member 10D are suppressed, thereby suppressing misalignment. The attachment method of the ion shielding member 10D to the through-hole 61 is not particularly limited, and any method may be adopted including but not limited to the above-described attachment method.

### Fifth Embodiment

A film forming apparatus 1E according to a fifth embodiment of the present disclosure will be described with reference to FIG. 10. FIG. 10 is a longitudinal side view showing a film forming apparatus according to the fifth embodiment. The film forming apparatus of the fifth embodiment is different from that of the first embodiment in that the processing space S1 formed in the processing chamber 5 serves as the plasma generation space S2. Therefore, the sheath region R1 is also formed on the inner wall surface of the processing chamber 5 located in the processing space S1, or the end surface of the exhaust line 87. Accordingly, ions are incident thereon, which may cause discharge. In particular, at the upper end surface of the opening 56 constituting the exhaust channel, the exhaust flow containing plasma flows in, so that discharge is likely to occur near the plasma region R2.

For example, in the film forming apparatus 1E shown in FIG. 10, a perforated plate 6E is provided as a rectifying plate for uniformly exhausting a gas from the vicinity of the placing table 8 by suppressing occurrence of drift in which the processing gas (reactive gas or raw material gas) supplied to the processing space S1 flows directly toward the exhaust line 87. The perforated plate 6E is provided on the inlet side of the exhaust channel formed by the exhaust line 87. Further, the perforated plate 6E is not limited to this example, and may be located to directly cover the opening of the exhaust channel, which is the upper end surface of the opening 56.

If ions from the plasma of the processing gas that is generated in the processing space S1 are incident into the through-holes 61 formed in the perforated plate 6E, hollow cathode plasma may be generated, which may cause damages to the components and generate particles. Therefore, as in the embodiments described with reference to FIGS. 3 to 9, various ion shielding members 10 and 10B can be provided in the through-holes 61 of the perforated plate 6E. By providing the ion shielding members 10 and 10B, it is possible to block the incidence of ions on the upper surface 64 of the perforated plate 6E and allow the passage of the exhaust flow.

The processing performed on the substrate by the substrate processing apparatus according to the present disclosure may be another processing using plasma, such as etching, ashing, or the like, other than film formation. In addition, the substrate W to be processed in the substrate processing apparatus of the present disclosure is not limited to a semiconductor wafer, but may be a flat panel display (FPD) or the like.

Further, the embodiments of the present disclosure are illustrative in all respects and are not restrictive. Further, the above-described embodiments may be omitted, replaced, or changed in various forms without departing from the scope of the appended claims and the gist thereof.

1. A plasma processing apparatus for performing plasma processing by supplying a processing gas activated by plasma to a substrate in a processing chamber, comprising:
a placing table provided in the processing chamber and configured to place the substrate;
a plasma generation space constituting a plasma generation mechanism configured to convert the processing gas into plasma;
a processing gas supply part configured to supply the processing gas to the plasma generation space;
a perforated plate provided at a position where the processing gas converted into plasma flows out of the plasma generation space, the perforated plate having a plurality of through-holes through which the processing gas activated by plasma passes; and
an ion shielding member provided in the plurality of through-holes, having an ion shielding surface disposed to intersect a direction in which ions contained in the processing gas converted into plasma are incident toward the through-holes, and configured to allow the activated processing gas to pass through the through-holes where the incidence of ions is blocked by the ion shielding surface.

2. The plasma processing apparatus of claim 1, wherein the ion shielding member is formed in a cap shape and comprises a ceiling plate portion that constitutes the ion shielding surface and is disposed to cover the through-hole when viewed from the plasma generation space side, and a sidewall portion provided along an outer periphery of the ceiling plate portion, and
the sidewall portion has an opening for allowing the processing gas, in which the ions are trapped, to flow into the through-hole.

3. The plasma processing apparatus of claim 2, wherein the ion shielding member is arranged such that the ceiling plate portion protrudes toward the plasma generation space from a plate surface of the perforated plate, and
a protruding height of the ceiling plate portion is less than or equal to a thickness of an ion sheath formed on a surface of the perforated plate.

4. The plasma processing apparatus of claim 2, wherein the ion shielding member has a flange portion provided at a height position above a lower end of the sidewall portion and protruding outward from an outer peripheral surface of the sidewall portion, and is attached to the through-hole by inserting the sidewall portion located below the flange portion into the through-hole and bringing a bottom surface of the flange portion into contact with the plate surface of the perforated plate.

5. The plasma processing apparatus of claim 1, wherein the ion shielding member is a spiral-shaped member that is located in the through-hole and forms a spiral-shaped channel with respect to an inner wall surface of the through-hole, and
the ion shielding surface is formed by an inclined surface of the spiral-shaped member, the inclined surface being provided at a position facing the plasma generation space from an opening of the through-hole.

6. The plasma processing apparatus of claim 5, wherein the spiral-shaped member is formed in a shape that an elongated ribbon-shaped member having a width corresponding to a diameter of the opening of the through-hole is twisted around a central axis.

7. The plasma processing apparatus of claim 5, wherein the spiral-shaped member is formed in a shape that a spiral-shaped slope having a width from the central axis of the through-hole to the inner wall surface of the through-hole is formed around the central axis.

8. The plasma processing apparatus of claim 5, wherein the spiral-shaped member is fitted into a spiral-shaped groove formed on the inner wall surface of the through-hole.

9. The plasma processing apparatus of claim 1, wherein the ion shielding member is made of a metal or a dielectric.

10. The plasma processing apparatus of claim 9, wherein when the ion shielding member is made of a metal, the ion shielding member is covered with an oxide film or a dielectric.

11. The plasma processing apparatus of claim 1, wherein when the plasma generation space is formed above the placing table, the perforated plate is disposed between the plasma generation space and the placing table, and serves as a shower head for supplying the processing gas activated by plasma, generated in the plasma generation space, to the substrate placed on the placing table through the plurality of through-holes.

12. The plasma processing apparatus of claim 1, wherein, when the plasma generation space is formed in the processing chamber, the perforated plate is provided at an inlet side of an exhaust channel for exhausting a gas in the processing chamber.

13. A plasma processing method using a plasma processing apparatus which comprises a placing table provided in a processing chamber and configured to place a substrate, a plasma generation space constituting a plasma generation mechanism configured to convert a processing gas into plasma, a processing gas supply part configured to supply the processing gas to the plasma generation space, a perforated plate provided at a position where the processing gas converted into plasma flows out of the plasma generation space and having a plurality of through-holes through which the processing gas activated by the plasma passes; and an ion shielding member provided in the plurality of through-holes, having an ion shielding surface disposed to intersect a direction in which ions contained in the processing gas converted into plasma are incident toward the through-holes, and configured to allow the activated processing gas to pass through the through-holes where the incidence of ions is blocked by the ion shielding surface, the method comprising:
supplying the processing gas to the plasma generation space;
converting the processing gas supplied to the plasma generation space into plasma by the plasma generation mechanism;
allowing the activated processing gas to pass through the through-holes; and
supplying the activated processing gas to the substrate placed on the placing table before or after said allowing the activated processing gas to pass through the through-holes.
